(19) United States
(12) Patent Application Publication
(10) Pub. No.: US 2025/0022722 A1
(43) Pub. Date: Jan. 16, 2025

(54) METHOD FOR MANUFACTURING SUBSTRATE

(71) Applicant: HAESUNG DS CO., LTD., Gyeongsangnam-do (KR)

(72) Inventor: Jongwoo PARK, Gyeongsangnam-do (KR)

(21) Appl. No.: 18/771,243

(22) Filed: Jul. 12, 2024

(30) Foreign Application Priority Data
Jul. 13, 2023 (KR) 10-2023-0091381

(51) Int. Cl. H01L 21/48; C25D 7/12

(52) U.S. Cl. CPC H01L 21/4846; C25D 7/12

(57) ABSTRACT

According to an aspect of the disclosure, a method of manufacturing a substrate having a semiconductor chip receiving recess formed therein, includes preparing a copper-clad laminate having, on at least one surface thereof, a copper-clad layer, forming a first plating pattern on one surface of the copper-clad layer so as to correspond to a position at which the semiconductor chip receiving recess is to be formed, forming a second plating pattern on one surface of the first plating pattern and one surface of the copper-clad layer, arranging an insulating layer to cover the first plating pattern and the second plating pattern, and forming the semiconductor chip receiving recess by removing a portion of the copper-clad layer, on which the first plating pattern is arranged, and the first plating pattern.

### CROSS-REFERENCE TO RELATED APPLICATION

This application is based on and claims priority under 35 U.S.C. § 119 to Korean Patent Application No. 10-2023-0091381, filed on Jul. 13, 2023, in the Korean Intellectual Property Office, the disclosure of which is incorporated by reference herein in its entirety.

### BACKGROUND

### 1. Field

The disclosure relates to a method of manufacturing a substrate.

### 2. Description of the Related Art

A substrate may generally include a wiring pattern printed with a conductive material such as copper on an electrically insulating material, and electronic components such as semiconductor chips may be mounted on the substrate.

Recently, in the electrical and electronic industries, the trend toward miniaturization, simplification, and higher performance of various products and parts has become prominent. In particular, fast electrical performance, low power operation, and electromagnetic wave shielding are required for substrates and semiconductor packages used in various products such as PCs and smartphones.

Following this trend toward higher performance, a semiconductor package of a package-on-package type has been developed, which realizes vertical expansion by stacking baseband chips and memories.

Semiconductor packages of a package-on-package type have a stacked structure of multiple substrates, which has the disadvantage of increasing the overall thickness. To address this disadvantage, by forming a recess in a lower substrate of laminated substrates and arranging semiconductor chips in the recess, not only may the thickness of the package be reduced, but an interposer substrate for adjusting the height may be omitted.

Korean Patent Publication No. 10-2018-0037988 discloses a silicon substrate having a recess formed therein and a chip installed in the recess.

### SUMMARY

According to an aspect of the disclosure, the main object is to provide a method for manufacturing a substrate on which receiving recesses, in which semiconductor chips are to be arranged, and wiring patterns may be formed efficiently.

According to an aspect of the disclosure, a method of manufacturing a substrate having a semiconductor chip receiving recess formed therein, includes preparing a copper-clad laminate having, on at least one surface thereof, a copper-clad layer; forming a first plating pattern on one surface of the copper-clad layer so as to correspond to a position at which the semiconductor chip receiving recess is to be formed; forming a second plating pattern on one surface of the first plating pattern and one surface of the copper-clad layer; arranging an insulating layer to cover the first plating pattern and the second plating pattern; and forming the semiconductor chip receiving recess by removing a portion of the copper-clad layer, on which the first plating pattern is arranged, and the first plating pattern.

Here, the copper-clad laminate may include a double-sided copper-clad laminate having a copper-clad layer laminated on both sides.

Here, the copper-clad laminate may include a copper-clad laminate for an embedded trace substrate (ETS).

Here, the first plating pattern may be formed by copper plating. Here, the second plating pattern may be formed by copper plating.

Here, the insulating layer may include a prepreg material.

Here, the removing of the first plating pattern may be performed on the opposite side to the one surface of the first plating pattern.

Here, the method may further include forming a solder resist layer on the substrate after the forming of the semiconductor chip receiving recess.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a semiconductor package of a package-on-package type using a substrate, according to an embodiment of the disclosure.

FIGS. 2 to 15 are views sequentially illustrating a substrate manufacturing process, according to an embodiment of the disclosure.

FIG. 16 is a schematic flowchart illustrating a substrate manufacturing process, according to an embodiment of the disclosure.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Expressions such as “at least one of,” when preceding a list of elements, modify the entire list of elements and do not modify the individual elements of the list.

Hereinafter, the disclosure according to preferred embodiments will be described in detail with reference to the attached drawings. In addition, in this specification and drawings, components having substantially the same configuration are denoted by the same symbols to omit redundant descriptions, and in the drawings, there may be exaggerated portions in size, length ratio, etc. to help understanding.

The disclosure will become more apparent by reference to the embodiments described below in detail together with the accompanying drawings. However, the disclosure is not limited to the embodiments disclosed below, but may be implemented in various different forms, and these embodiments are provided only to make the disclosure of the disclosure complete and to fully inform a person having ordinary skill in the art to which the disclosure belongs of the scope of the disclosure, and the disclosure is defined only by the scope of the claims.

Meanwhile, the terms used in this specification are for the purpose of describing embodiments and are not intended to limit the disclosure. In this specification, singular forms also include plural forms unless specifically stated otherwise in the text. The terms “comprises” and/or “comprising”, as used in the specification, do not exclude the presence or addition of one or more other components, steps, operations and/or elements. The terms “first, second,” etc. may be used to describe various components, but the components should not be limited by the terms. The terms are used solely to distinguish one component from another.

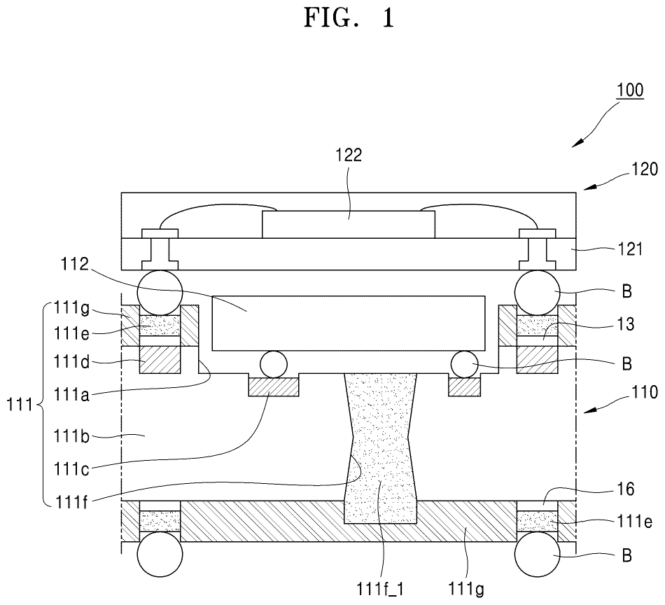

FIG. 1 is a cross-sectional view of a semiconductor package of a package-on-package type using a substrate, according to an embodiment of the disclosure.

As illustrated in FIG. 1, a semiconductor package 100 according to an embodiment of the disclosure is a package-on-package type semiconductor package, in which a first semiconductor package 110 and a second semiconductor package 120 are stacked.

The first semiconductor package 110 includes a first substrate 111 and a first semiconductor chip 112 arranged on the first substrate 111.

The first substrate 111 includes a semiconductor chip receiving recess 111a, an insulating layer 111b, a first wiring pattern 111c, a second wiring pattern 111d, a third wiring pattern 111e, a via hole 111f, and a solder resist layer 111g.

The first semiconductor chip 112 is arranged in the semiconductor chip receiving recess 111a.

The insulating layer 111b may include a prepreg material.

The first wiring pattern 111c is a portion electrically connected to a terminal of the first semiconductor chip 112 and a solder ball B. In this specification, the term ‘solder ball B’ refers to a structure for electrical connection, such as a solder bump or copper pillar, and is a concept that can be used interchangeably.

The second wiring pattern 111d and the third wiring pattern 111e function as wiring patterns of the first substrate 111.

The second semiconductor package 120 installed above the first semiconductor package 110 includes a second substrate 121 and a second semiconductor chip 122 arranged on the second substrate 121, and is electrically connected to the first substrate 111 via the solder ball B.

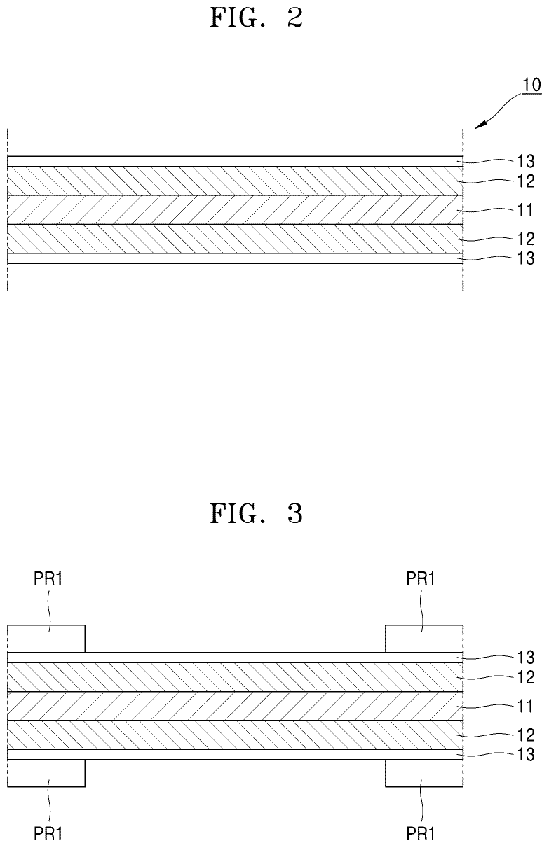

The present embodiment relates to a method of manufacturing the first substrate 111 having the semiconductor chip receiving recess 111a formed therein. Hereinafter, the method of manufacturing the first substrate 111 will be described with reference to FIGS. 2 to 16.

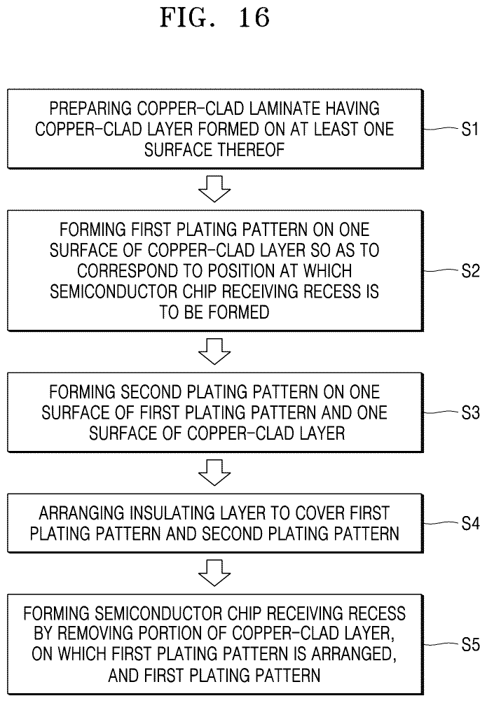

FIGS. 2 to 15 are views sequentially illustrating a substrate manufacturing process, according to an embodiment of the disclosure, and FIG. 16 is a schematic flowchart illustrating a substrate manufacturing process, according to an embodiment of the disclosure.

First, as illustrated in FIG. 2, the manufacturer prepares a copper-clad laminate 10 having a copper foil formed on both sides thereof (operation S1).

As the copper-clad laminate, a double-sided copper-clad laminate for an embedded trace substrate (ETS) is prepared.

The copper-clad laminate 10 includes a carrier portion 11, a first copper-clad layer 12, and a second copper-clad layer 13.

There is no special limitation on the material of the carrier portion 11, and the material may include an insulating film, etc.

The first copper-clad layer 12 includes copper and may have a thickness of about 18 μm.

The second copper-clad layer 13 includes copper and may have a thickness of about 2 μm.

The thicknesses of the first copper-clad layer 12 and the second copper-clad layer 13 according to the present embodiment may be about 18 μm and about 2 μm, respectively, but the disclosure is not limited thereto. That is, according to the disclosure, there is no special limitation on the thickness of the first copper-clad layer 12 and the second copper-clad layer 13.

As the copper-clad laminate 10 according to the present embodiment, a commercial copper-clad laminate for an ETS may be used, but the disclosure is not limited thereto. That is, the copper-clad laminate according to the disclosure may be applied without limitation as long as the copper-clad laminate is a laminate having a copper foil formed on at least one surface thereof.

Next, a first plating pattern 14 is formed on one surface of the second copper-clad layer 13 by copper plating, and a position where the first plating pattern 14 is formed corresponds to a position where the semiconductor chip receiving recess 111a is formed later (operation S2).

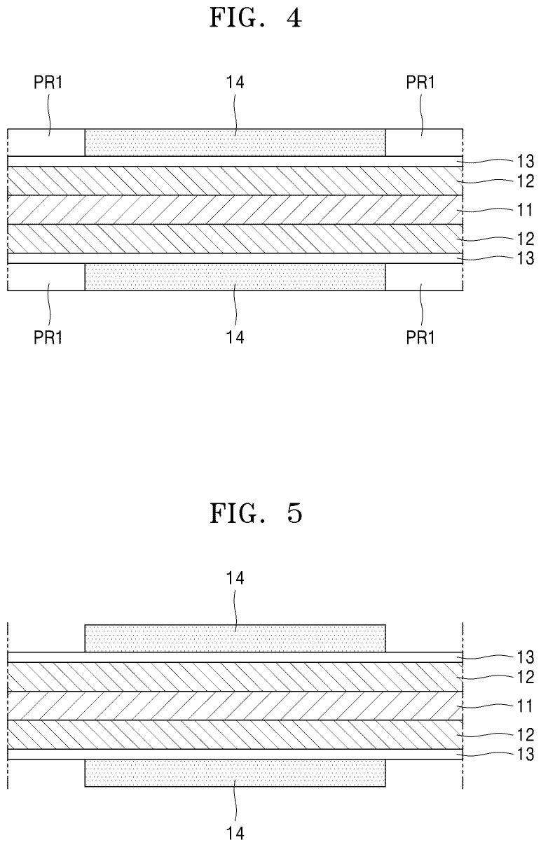

To this end, as illustrated in FIG. 3, a first plating resist pattern PR1 is formed on one surface of the second copper-clad layer 13, the first plating pattern 14 is formed by electrolytic plating or electroless plating as illustrated in FIG. 4, and the first plating resist pattern PR1 is removed as illustrated in FIG. 5.

Here, the first plating resist pattern PR1 may be formed by a photolithography process. For example, after placing a plating resist layer, an etching resist is formed on the plating resist layer by dry film laminating, exposure, development, etc., and then an etching material may be applied to form the first plating resist pattern PR1 at a designed position.

The formation thickness of the first plating pattern 14 may be determined by considering the thickness of the first semiconductor chip 112 arranged on the first substrate 111. That is, since the thickness of the first plating pattern 14 is almost the same as the size of the semiconductor chip receiving recess 111a, the thickness of the first plating pattern 14 is determined by considering the thickness of the first semiconductor chip 112 received in the semiconductor chip receiving recess 111a.

The first plating pattern 14 according to the present embodiment includes copper, but the disclosure is not limited thereto. That is, any material that may be plated may be applied without limitation as the material of the first plating pattern 14) according to the disclosure. For example, the first plating pattern 14) may include various materials including a single metal such as gold or silver, a copper alloy, etc.

Next, a second plating pattern 15 is formed by copper plating on one surface 14a of the first plating pattern 14 formed and one surface 13a of the second copper-clad layer 13 (operation S3).

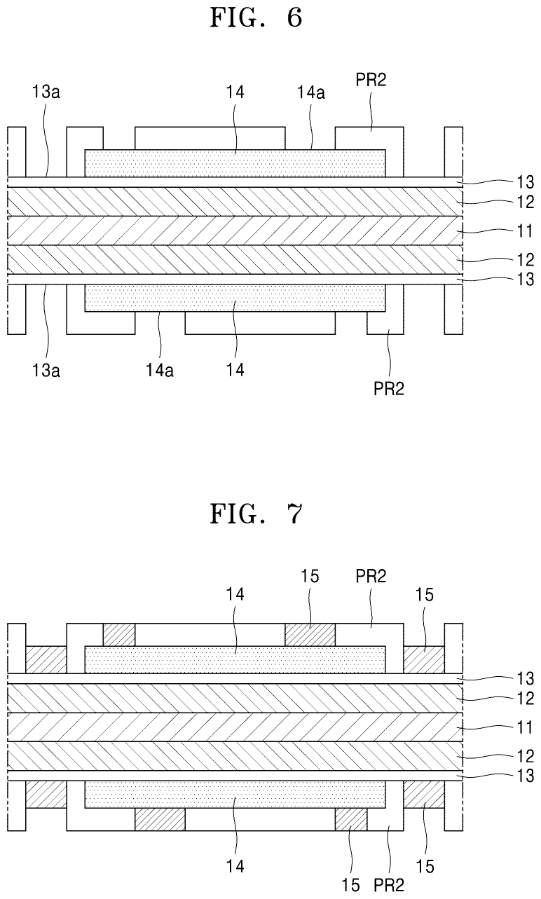

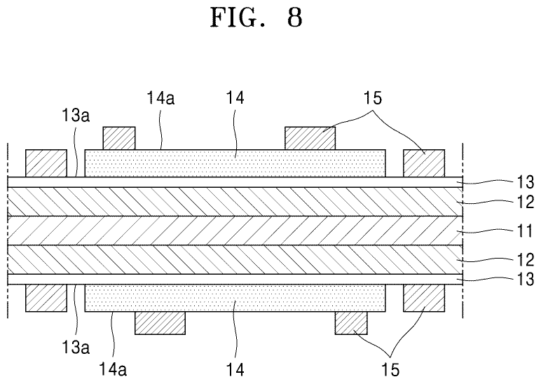

To this end, as illustrated in FIG. 6, a second plating resist pattern PR2 may be formed on one surface 13a of the second copper-clad layer 13 and the first plating pattern 14, a second plating pattern 15 is formed by electrolytic plating or electroless plating as illustrated in FIG. 7, and the second plating resist pattern PR2 is removed as illustrated in FIG. 8.

Here, the second plating resist pattern PR2 may be formed by a photolithography process. For example, after placing a plating resist layer, an etching resist is formed on the plating resist layer by dry film laminating, exposure, development, etc., and then an etching material is applied to form a second plating resist pattern PR2 at a designed location.

The second plating pattern 15 according to the present embodiment includes copper, but the disclosure is not limited thereto. That is, any material that may be plated may be applied without limitation as the material of the second plating pattern 15) according to the disclosure. For example, the second plating pattern 15) may include various materials including a single metal such as gold or silver, a copper alloy, etc.

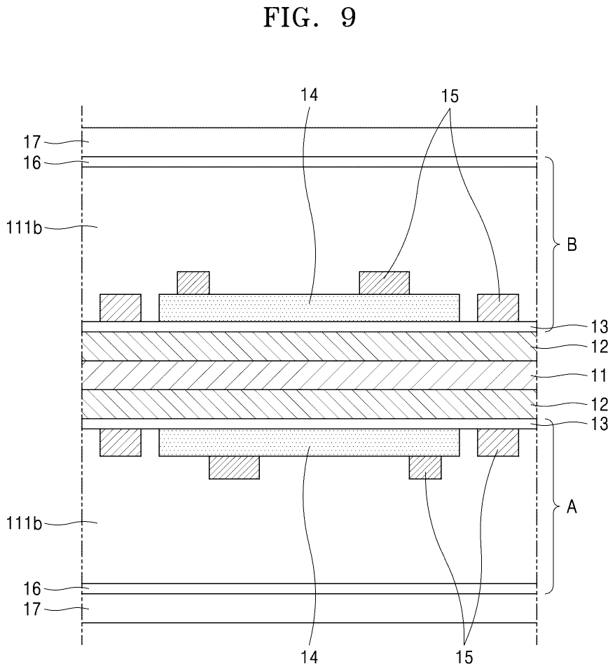

Next, as illustrated in FIG. 9, an insulating layer 111b is arranged to cover the first plating pattern 14 and the second plating pattern 15 (operation S4).

The insulating layer 111b includes a prepreg material, and a prepreg material in a b-stage state may be laminated.

The insulating layer 111b according to the present embodiment includes a prepreg material, but various materials other than the prepreg material may be applied without limitation as the material of the insulating layer 111b) of the disclosure. For example, the material of the insulating layer 111b) may include various insulating materials such as a prepreg material, an epoxy material, a silicone-based material, and a urethane-based material, and a state before curing may also include various states such as a liquid and a paste.

A third copper-clad layer 16 and a fourth copper-clad layer 17 are formed on an outer surface of the insulating layer 111b arranged. This is to facilitate handling of the insulating layer 111b, and the thickness of the third copper-clad layer 16 and the fourth copper-clad layer 17 may have a thickness of about 2 μm and a thickness of about 18 μm, respectively, but there is no particular limitation on the thickness.

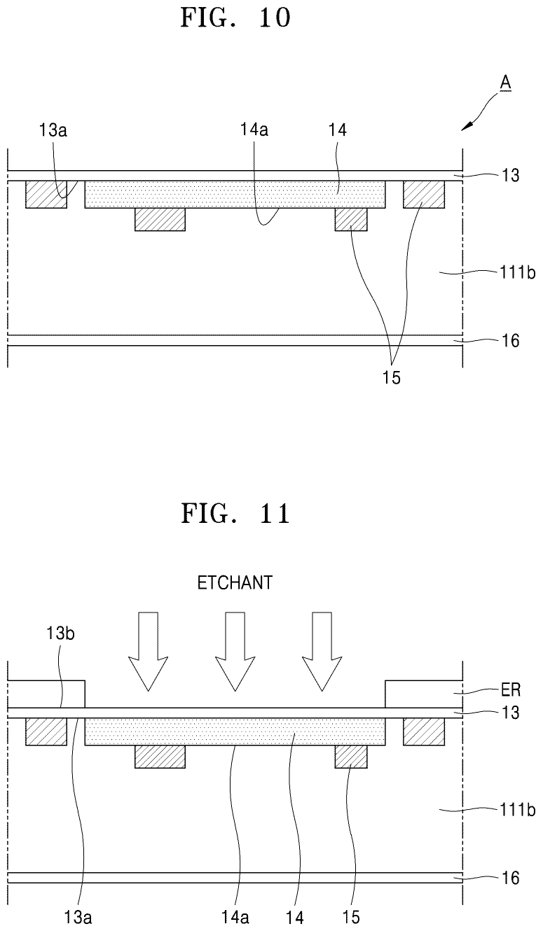

Next, the carrier portion 11, the first copper-clad layer 12, and the fourth copper-clad layer 17 are removed, separated into portion A and portion B of FIG. 9, and a next process is performed. The separation process may be performed by physically applying force or by an etching method through which the first copper-clad layer 12 and the fourth copper-clad layer 17 are removed. This process is intended to manufacture two substrates simultaneously by dividing laminates into portion A and portion B, since the copper-clad laminate 10 used in the present embodiment is a double-sided copper-clad laminate. FIG. 10 is a drawing of portion A of FIG. 9, in which the second copper-clad layer 13 and the third copper-clad layer 16 are exposed on the outer surface. Hereinafter, a manufacturing method using portion A among the divided portions will be described as an example.

In a state as illustrated in FIG. 10, a semiconductor chip receiving recess 111a is formed by removing a portion of the second copper-clad layer 13, on which the first plating pattern 14 is arranged, and the first plating pattern 14 (operation S5).

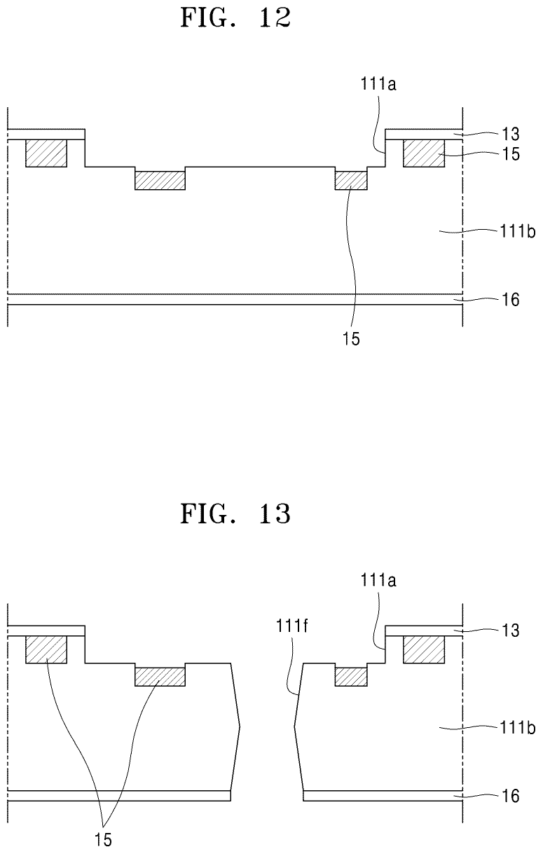

To this end, as illustrated in FIG. 11, an etching resist pattern ER is formed on the other surface 13b of the second copper-clad layer 13, and an etchant is applied to the opposite side of one surface 14a of the first plating pattern 14 to remove the portion of the second copper-clad layer 13, on which the first plating pattern 14 is arranged, and the first plating pattern 14, thereby forming the semiconductor chip receiving recess 111a as illustrated in FIG. 12.

In wet etching using an etchant, a copper chloride or iron chloride etching material may be used as an etchant, and the etchant may be applied using a spraying method, etc.

According to the present embodiment, a wet etching method using an etchant is used to form the semiconductor chip receiving recess 111a, but the disclosure is not limited thereto. That is, according to the disclosure, various methods such as dry etching and laser processing may be used to form the semiconductor chip receiving recess 111a without using an etchant.

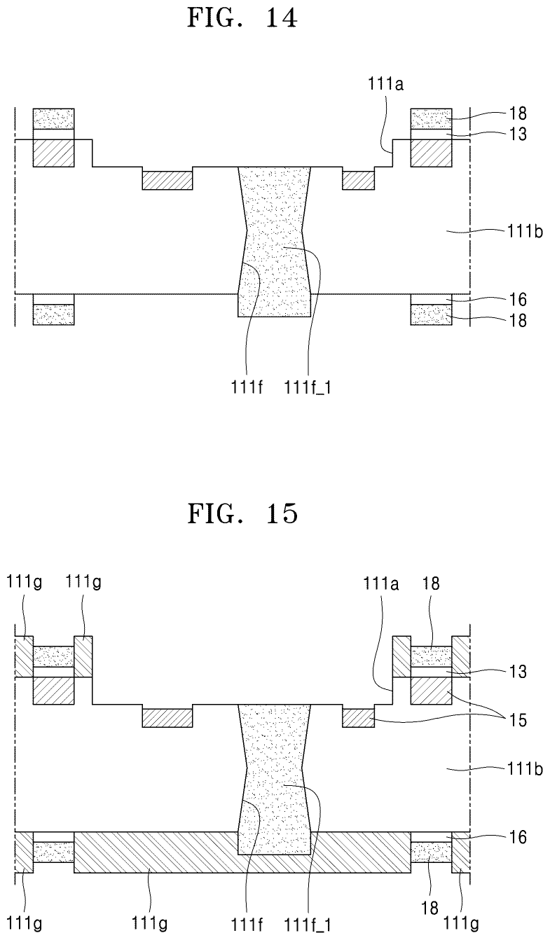

Next, as illustrated in FIG. 13, a via hole 111f is formed in the first substrate 111 by etching or laser processing, and as illustrated in FIG. 14, a conductive connection layer 111f_1 is formed in the via hole 111f, and the second copper-clad layer 13 and the third copper-clad layer 16 are flash etched to form a pattern, and a third plating pattern 18 is formed on the remaining pattern portion.

Next, as illustrated in FIG. 15, a solder resist layer 111g is formed in required portions to complete the first substrate 111. Comparing FIG. 15 with FIG. 1, the second plating pattern 15 of FIG. 15 corresponds to the first wiring pattern 111c and the second wiring pattern 111d of FIG. 1, and the third plating pattern 18 of FIG. 15 corresponds to the third wiring pattern 111e of FIG. 1.

A method of manufacturing a semiconductor package 100 using the first substrate 111 completed as above is briefly described as follows.

To complete the first semiconductor package 110, a first semiconductor chip 112 is arranged in the semiconductor chip receiving recess 111a and connected with a solder ball B to complete the first semiconductor package 110. Next, a second semiconductor package 120 is arranged on the first semiconductor package 110 to manufacture the semiconductor package 100 of a package-on-package type, and for electrical connection, here, solder balls B may be used.

The manufacturing process of the first substrate 111 above may be performed as a roll-to-roll process, but may also be performed on a panel-by-panel basis. If a roll-to-roll process is used as in the present embodiment, the first substrate 111 may be manufactured quickly and in large quantities.

According to the method of manufacturing the first substrate 111 according to the present embodiment as described above, the first plating pattern 14 is formed at a location where the semiconductor chip receiving recess 111a is to be formed among portions of the second copper-clad layer 13, the second plating pattern 15 is formed on the first plating pattern 14 and the second copper-clad layer 13, the insulating layer 111b is disposed to cover the first plating pattern 14 and the second plating pattern 15, and then the semiconductor chip receiving recess 111a is formed by removing the portion of the second copper-clad layer 13, on which the first plating pattern 14 is disposed, and the first plating pattern 14, and thus, the semiconductor chip receiving recess 111a, the first wiring pattern 111c, and the second wiring pattern 111d may be formed simply and efficiently.

In addition, according to the method of manufacturing the first substrate 111 according to the present embodiment, since a double-sided copper-clad laminate is used as the copper-clad laminate 10, two substrates may be manufactured simultaneously.

According to the method of manufacturing a first substrate according to an aspect of the disclosure, a first plating pattern is formed at a location where a semiconductor chip receiving recess is to be formed among portions of a copper-clad layer, a second plating pattern is formed on the first plating pattern and the copper-clad layer, an insulating layer is disposed to cover the first plating pattern and the second plating pattern, and then the portion of the copper-clad layer, on which the first plating pattern is disposed, and the first plating pattern are removed to form a semiconductor chip receiving recess, and thus, the semiconductor chip receiving recess and wiring patterns may be formed simply and efficiently.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method of manufacturing a substrate having a semiconductor chip receiving recess formed therein, the method comprising:
preparing a copper-clad laminate having, on at least one surface thereof, a copper-clad layer;
forming a first plating pattern on one surface of the copper-clad layer so as to correspond to a position at which the semiconductor chip receiving recess is to be formed;
forming a second plating pattern on one surface of the first plating pattern and one surface of the copper-clad layer;
arranging an insulating layer to cover the first plating pattern and the second plating pattern; and
forming the semiconductor chip receiving recess by removing a portion of the copper-clad layer, on which the first plating pattern is arranged, and the first plating pattern.

2. The method of claim 1, wherein the copper-clad laminate comprises a double-sided copper-clad laminate having a copper-clad layer laminated on both sides.

3. The method of claim 1, wherein the copper-clad laminate comprises a copper-clad laminate for an embedded trace substrate (ETS).

4. The method of claim 1, wherein the first plating pattern is formed by copper plating.

5. The method of claim 1, wherein the second plating pattern is formed by copper plating.

6. The method of claim 1, wherein the insulating layer comprises a prepreg material.

7. The method of claim 1, wherein the removing of the first plating pattern is performed on an opposite side to the one surface of the first plating pattern.

8. The method of claim 1, further comprising forming a solder resist layer on the substrate after the forming of the semiconductor chip receiving recess.
